(19) United States
(12) Patent Application Publication
(10) Pub. No.: US 2026/0009824 A1
(43) Pub. Date: Jan. 8, 2026

(54) Input Facility, Controller, and Measurement Apparatus

(71) Applicant: Siemens Aktiengesellschaft, Muenchen (DE)

(72) Inventors: Gunter GRIESSBACH, Dresden (DE); Dirk PROCHASKA, Chemnitz (DE); Alexander HELMDACH, Chemnitz (DE); Robert WEIKERT, Burggriesbach (DE); Oliver RAAB, Ortenburg (DE)

(21) Appl. No.: 19/258,336

(22) Filed: Jul. 2, 2025

(30) Foreign Application Priority Data
Jul. 4, 2024 (EP) 24186427

(51) Int. Cl. G01R 13/02; G01R 15/12; H03K 5/01

(52) U.S. Cl. CPC G01R 13/0218; G01R 15/125; H03K 5/01

(57) ABSTRACT

An input facility for a controller or measurement apparatus includes at least one input circuit for providing at least one digital or at least one analog input for a controller or measurement apparatus, wherein the at least one input circuit includes at least one phase modulation converter that has an amplitude modulator with carrier suppression to which an input signal can be supplied on the input side in order to obtain a carrierless amplitude-modulated signal, an adder for adding a carrier signal shifted by 90° to the carrierless amplitude-modulated signal and for obtaining a phase-modulated signal, a limiter to which the phase-modulated signal is supplied and with which a noise amplitude modulation in the phase-modulated signal can be suppressed, and a demodulation facility to which the signal output from the limiter is supplied and that can be sampled therein with at least one sampling clock signal.

### BACKGROUND OF THE INVENTION

### 1. Field of the Invention

The invention relates to a controller or measurement apparatus with at least one input facility, use of the input facility, use of a phase modulation converter and to the input facility, in particular to an input module, for a preferably programmable logic controller or for a measurement apparatus, in particular an oscilloscope or a preferably digital multimeter, where the input facility comprises at least one input circuit in order to provide at least one digital or at least one analog input for a controller or measurement apparatus.

### 2. Description of the Related Art

In the industrial environment above all there exist diverse requirements for controllers and measurement apparatuses that are employed.

There are thus requirements for digital inputs in the industrial environment. These include a corresponding characteristic current and voltage input curve for compatibility with widely—used sensors. A plurality of different input voltage ranges are used in the industrial environment (24 VDC, 48 VDC, 110 VDC (rail) and also 110/120/230 VAC), which must adhere to different characteristic input curves. As a result, it is a challenge to build a digital input that can be employed over a wide range of voltages. Therefore, it is usual for different circuits to be realized for the various input voltage classes. This leads to increased diversity of components and to higher outlay for repair and maintenance.

There is often also a need in controllers or measurement facilities for an electrical isolation to be realized for an evaluation logic of the device. For digital inputs according to the programmable logic controller (PLC) standard, for example, it is a requirement to provide a galvanic isolation from the logic. This galvanic isolation is frequently a problem area for adhering to the Electromotive Force (EMF) resistance demanded by the standard. This means that additional EMF measures are mostly inevitable.

Various options for a solution are known to the applicant for bringing the information of a digital input via an electrical isolation. The simplest type consists in using optocouplers. The disadvantage here is that these always need a specific current on the send diode side to transport the information reliably. The evaluation on the logic side is based on the current transmission ratio (CTR) of the optocoupler. Unfortunately, the current transmission ratio is dependent on many factors, such as the LED current itself, the ambient temperature and also very heavily on the aging of the component. The consequence of this is that, for a reliable transmission of information, the current through the sender LED must be over-dimensioned. This current is taken from the 24V process side, for example, and consequently thus has an increased power loss and a higher derating of PLC modules.

An alternative to optical transmission consists in using capacitive or inductive data couplers. These couplers only serve to transmit the information across the electrical isolation. The corresponding components are fabricated in standard industry pinouts and are frequently very widely interchangeable with one another. The disadvantage here is that, for example, the 24V digital input must be scaled down to a logic voltage level (CMOS), so that a usable supply voltage must be made available. Here, too, data couplers with integrated supply voltage are available, but these are even more expensive than the pure data couplers, however.

Also known to the applicant is that a few suppliers offer special application-specific integrated circuits (ASICs) to offer the complete function of characteristic curve and electrical isolation together in one integrated circuit (IC). The disadvantage here is that such specialized solutions have no alternative on the market. If a design is built with corresponding ASICs, then in the case of a component/supplier crisis there is no alternative supplier available.

For use as per standards in industry applications it is necessary to achieve a minimum amount of electromagnetic compatibility (EMC) or EM resistance. In the past it has been shown that above all it is a matter of the electrical isolation already described for noise influencing. Regardless of which of the transmission principles (optical, capacitive, inductive) is used, a sensitivity to transient faults (common-mode and/or differential) always exists. So that a corresponding EM resistance can be achieved, it was always necessary to filter both the input signal itself corresponding strongly (requirement 61000-4-6 HF current supply as from 10 kHz), and also to ensure that in the case of a rapid transient (61000-4-4 burst) the gradient of the voltage change between the two connected potentials stays within the specified range. The capacitors, which are thus necessary externally in parallel to the separation path, on the one hand, drive up the price further and bring problems with them for safety considerations for mixed operation of standard and failsafe modules, for example in a PLC rack. In the known manner, the abbreviation PLC stands for programmable logic controller in this case.

Regardless of whether digital inputs, digital outputs or the analog variants have to be realized in PLC modules, as a rule the requirement for an electrical isolation always exists. It would now be advantageous for this logical block to be able to be constructed together with the evaluation logic, in an ASIC, for example. The abovementioned methods are only able to be integrated with difficulty however, because there is both a conflict as regards the necessary processes and also in the fabrication technology (for example, a number of dies in a chip). Currently this not able to be realized economically in large volumes.

A further problem consists in additional mechanisms being necessary to read in input signals over a plurality of channels synchronously. An example of an integrated circuit is known to the applicant in which the time is triggered via an extra logic pin. This information is transmitted internally across the electrical isolation and the channels are enabled or disabled accordingly. In order to establish the state of the number of input channels at an exact time of day, there must furthermore be a runtime equalization in the firmware. If such a function is to be realized based on the optocoupler circuits, additional switch elements beyond the electrical isolation are needed.

Solutions are further known to the applicant in which, as is usual in industrial applications, a plurality of channels lie at the same reference potential, in which insulated analog-digital converters sample the state of the connected inputs. Through the use of synchronous converters, in this case, the temporal reference of the signals to one another is clearly defined. This solution is complex and costly, however.

An analog-digital converter serves to convert an analog input variable into a digitized signal. Known analog-digital converters are the SAR (Successive Approximation) converter and the Sigma-Delta converter, for example. Both converter types have disadvantages associated with them, which result from DC voltage errors of the analog input signal.

EP 3 624 334 A1 discloses a further developed apparatus for conversion of an analog input signal into a digital output signal. Specifically, this involves an analog-digital converter (AD converter), which is based on the difference of the phase position of a signal modulated to the input voltage to be measured compared to a reference signal. The analog-digital converter previously known from EP 3 624 334 A1 can also be referred to as a phase modulation converter.

The phase modulation converter in accordance with EP 3 624 334 A1 comprises an amplitude modulator with carrier suppression for providing a carrierless amplitude modulated signal. The amplitude modulator has a signal input to which an analog input signal to be converted can be supplied. An adder is also present to which the carrierless amplitude modulated signal output by the amplitude modulator is supplied and which is configured to add a carrier signal shifted by 90° to this and to provide a phase modulated signal. Furthermore, a limiter is present to which the phase modulated signal output by the adder is supplied and which is configured to suppress a noise amplitude modulation in the phase modulated signal.

The resulting output signal of the limiter has an amplitude, which consists of 0 or 1. It can also be said that a signal digital in its amplitude is present. The length of these pulses is continuous in value depending on the weighted carrier frequency. The information is held in the length of the square-wave pulse. The output signal of the limiter carries the modulation in temporally different zero crossings compared to the 90° carrier signal. The reader is referred in this context to the figures of EP 3 624 334 A1, in particular FIGS. 5 to 8 contained therein along with the associated description, which explain the principle in more detail.

### SUMMARY OF THE INVENTION

Using the foregoing as its starting point, it is an object of the present invention to provide an apparatus that offers a good level of EM resistance, adapts itself at reasonable expense to various voltage ranges and can be produced in a multichannel embodiment and at the same time at low cost.

These and other objects and advantages are achieved in accordance with the invention by an input facility and by at least one input circuit comprising at least one phase modulation converter, where the at least one phase modulation converter includes an amplitude modulator with carrier suppression to which an input signal can be supplied on the input side to obtain a carrierless amplitude-modulated signal, includes an adder for adding a preferably sinusoidal carrier signal shifted by 90° to the carrierless amplitude-modulated signal and for obtaining a phase-modulated signal, includes a limiter to which the phase-modulated signal is supplied and with which a noise amplitude modulation in the phase-modulated signal can be suppressed, and includes a demodulation facility to which the signal output by the limiter is supplied and within which there can be sampling with at least one sampling clock signal.

In other words, the present invention makes provision for constructing inputs of industrial controllers or measurement apparatuses based on one or more phase modulation converters that offer significant advantages compared to conventional input facilities.

On the one hand, there can a very simple and convenient electrical isolation in a phase modulation converter dictated by structure, for example, by coupling capacitors. This can be at practically any given point in the signal path. No intelligent capacitive/inductive transformers are necessary. Accordingly, in a preferred embodiment of the inventive input facility, at least one galvanic isolation is provided between the amplitude modulator and the demodulation facility of the at least one phase-modulation converter, which preferably comprises at least one pair of coupling capacitors or is formed by said capacitors.

The mechanism of the phase-modulation converter is universal and can easily be integrated, into a bus ASIC, for example, in particular into the demodulator of the phase-modulation converter. It is precisely because the approach brings this universality with it that there can be an integration in a simple manner. Quite regardless of whether digital or analog input modules are to be constructed, the manner of the signal transmission can always remain the same and can therefore be used for a large spectrum of components. Furthermore, the integration of the necessary components is markedly simpler than the integration of previous technologies in which a plurality of chips are frequently stacked horizontally or vertically, packed into a housing. All necessary components that must be integrated are based either on logic elements or on simple analog circuits, which significantly simplifies the integration. A mixed-signal process is easier and more convenient to realize and operate than the increased effort in construction and connection technology for the connection of various chips.

The transmission of the information in the phase modulation converter occurs in the frequency range. As a result, in principle, a higher EM resistance is further produced. By comparison with capacitive/inductive couplers, there is no necessity for limiting the rise time of common-mode noise, because this is suppressed at the separation point. Large, expensive filter capacitors across the separation point can thus be dispensed with, which improves the integrability as well as the cost position. For purposes of completeness, it should be noted that capacitors are or can be built in beyond the separation point, but then in particular to transmit the signal and not in order to brake the transients. The advantage lies in particular in the fact that a transient causes a differential transmission on both lines and thus practically does not arrive in the useful signal.

A further advantage of the use of a phase-modulation converter for inputs of controllers or a measurement apparatus is given by a phase modulation converter always being analog. In particular, for the case in which a phase modulation converter is used for a digital input, it can be said that there is analog analysis of a digital signal or the digital state.

In a phase modulation converter, there is no transmission of “1 and 0”, but an analog sampling in particular of the restricted signal. This is also in the case in which a phase modulation converter is used for a digital input, i.e., for digital signals. In the analog range it is possible, as well as the states “1 and 0”, to also cover additional situations, in particular a third state. This can be used in order, together with the actual signal state, to transmit diagnostic information, such as information about a wire or line break, to do this without an additional channel being necessary for it. By contrast, this is necessary as a rule in accordance with the prior art. For a PLC channel capable of diagnosis, previously, for example, the signal state would be transmitted via one optocoupler and the information about the wire/line break via a further optocoupler. In other words, an additional channel across the electrical isolation was necessary for the diagnostic function. Through the omission of this requirement for use of a phase-modulation converter channels with a diagnostic function can be obtained with which markedly less effort and thus lower costs are associated.

It is further advantageous that for the realization of digital inputs for various voltage ranges in a simple manner, only in particular elements connected upstream from the amplitude modulator of the at least one phase-modulation converter, such as a signal processing module connected upstream of said converter, can be adapted in order to adhere to the characteristic curves demanded by the standard. The function block of the information transmission, also across an electrical isolation, can be kept universal. In particular, no change to the (respective) amplitude modulator, adder or limiter is required. By comparison with ready-made couplers, an additional degree of freedom is produced. Depending on the air gap and creepage distance required, only the distance to the printed circuit board and also the dielectric strength of the coupling capacitors must be adapted to an electrical separation that is expediently present.

Furthermore, there is already a construction-related element present with the amplitude modulator, which implicitly assumes “gating” of the input state at a specific point in time. The amplitude modulator can in particular be formed as a switch modulator, preferably CMOS switch modulator, or can at least comprise one such element. If the requirement for fast, clock-synchronously read-in input channels exists, this function can already be covered predominantly by the phase modulation converter.

In an expedient embodiment, the input signal is supplied to the amplitude modulator with carrier suppression at an input and an in particular square-wave or the sinusoidal carrier signal is supplied to the amplitude modulator at a further input. The inventive apparatus can be formed and/or configured accordingly. The carrier signal phase-offset by 90°, which is added via the adder to the amplitude-modulated signal, is phase offset in an expedient manner by 90° to that carrier signal that is supplied to the amplitude modulator. The frequency of this carrier signal particularly corresponds to the modulator frequency. This carrier signal particularly further represents a carrier to be suppressed.

In other words, the phase-modulated signal is formed from amplitude modulation of the input signal with a carrier and this carrier is suppressed in the amplitude modulator. The carrierless two-sideband signal is added to a 90° carrier. After limitation of this signal, a phase-modulated signal is available. The two-sideband signal contains sidebands each with the same information. The creation of an amplitude-modulated signal with carrier suppression means that the complex compensation for the carrier contained in the amplitude modulation is omitted. The addition of a new carrier, which is rotated by 90° in relation to the carrier that belongs to the AM signal, means that a phase-modulated signal with a maximum+/−90° phase deviation is obtained.

The input signal, which is supplied to the amplitude modulator with carrier suppression on the input side can, for example, involve an analog input signal to be converted. It can, however, also be a digital signal or in particular represent a signal to be interpreted digitally for superordinate controllers, which is first of all handled as an analog signal.

The amplitude modulator with carrier suppression can, for example, involve a (digital) switch modulator, such as a double push-pull modulator, or also a (digital) ring modulator. The switch modulator preferably comprises at least one in particular digital switch and/or at least one mechanical relay and/or at least one reed relay and/or at least one Micro Electro-Mechanical Systems (MEMS) switch or is given by such.

Expediently, there is a differential signal transmission in particular as from the outputs of the amplitude modulator and/or up to the output of the limiter or input of the demodulation facility. In an embodiment, the inventive apparatus is formed accordingly. Thus, at least beginning from the output of the amplitude modulator and in particular at least through to the output of the limiter or through to the demodulation facility, fine differential signal transmission is set up.

The adder can comprise at least one operational amplifier or be provided by this. In particular, the adder can involve at least one fully differential operational amplifier.

Preferably, a surface overlap between the limited signal and the reference signal is computed via the demodulation facility, this in particular over a plurality of periods. The demodulation facility can be configured accordingly.

It has proved especially advantageous for the modulation frequency to lie in the range of 1 MHz to 50 MHz. This is also because filters can be realized in a compact manner in this frequency range.

It has further proved especially advantageous for the signal output by the limiter signal to be sampled in the demodulation facility not only with one, but with a plurality of sampling clock signals phase-offset to one another. For example two, three, four or even more sampling clock signals are used for the sampling. If a plurality of sampling clock signals are employed, expediently these have a fixed phase offset to one another, i.e., they are phase-shifted. The fixed phase offset in this case is expediently chosen as a function of the number of the sampling clock signals. The fixed phase offset amounts in particular to 360°/m, where m corresponds to the number of sampling clock signals used for the sampling. The demodulation facility can be configured accordingly.

In a further advantageous embodiment, the phase position of the at least one sampling clock signal used for the sampling is dynamically changed to achieve an increased resolution, in particular by steps of less than 40°, preferably by steps of less than 20°, especially preferably by steps of less than 10°. The demodulation facility of the at least one phase-modulation converter of the inventive input facility is configured accordingly in an advantageous embodiment, and comprises the associated means, for example. The phase position of the one sampling clock signal or of the number of sampling clock signals being changed dynamically particularly that the phase position is changed multiple times, recurrently, preferably cyclically, continuously or quasi-continuously. Due to the dynamic phase shift the phase position of the sampling clock signal—or in the case of a plurality, in particular of all, the sampling clock signals, changes recurrently, for example cyclically, in fine steps. The change occurs in this case in particular at run time, such as program run time of the demodulation facility used for the demodulation, which comprise at least one Field-Programmable Gate Array (FPGA) and/or Application-Specific Integrated Circuit (ASIC) or is provided by at least one FPGA and/or ASIC and can be configured accordingly. The demodulation facility can in particular be configured to change the phase position of the at least one sampling clock signal at a plurality of consecutive points in time, in particular spaced equidistantly from one another, preferably where at least one microsecond lies between the spaced-apart points in time. The temporal spacing between consecutive points in time of the phase position change can for example lie in the range of 2 to 50 microseconds, preferably in the range of 5 to 50 microseconds.

If a plurality of sampling clock signals are used for the sampling, then in an advantageous embodiment these are all changed dynamically in their phase position. The dynamic, step-by-step phase position change of the number of sampling clock signals occurs in this case in an expedient manner synchronously in each case and/or by the same size steps, in particular of less than 40°. It is further true to say in an expedient manner that the dynamic, step-by-step phase position change of the number of sampling clock signals is undertaken such that the fixed phase offset that the number of sampling clock signals have in relation to one another remains in place. A clock generation facility of the demodulation facility can be configured accordingly.

Here, it should be stressed that an increase in resolution by dynamic phase shifting is purely optional. In particular, for the case in which one or more digital inputs is provided, a lower resolution can also suffice as a rule. Accordingly, it is also possible to increase the modulator frequency of the amplitude modulator. With this, on the one hand, the data rate increases and, on the other hand, filter elements can once again be significantly smaller.

It would also be conceivable to employ integrated filters, as are used in large numbers in the RFID/ISM area, for example. Filters for frequencies of 13.56 MHz or 27 MHz or 40 MHz or 433 MHz are given by way of example. In an embodiment, the inventive input facility can accordingly have at least one filter that is configured for a frequency of 13.56 MHz or 27 MHz or 40 MHz or 433 MHz. In particular, the at least one phase modulation converter of the inventive input facility includes at least one in particular analog filter, which is configured for a frequency of 13.56 MHz or 27 MHz or 40 MHz or 433 MHz.

The inventive input facility defines or implements at least one input or provides at least one such input. If the inventive input facility is built in the intended manner into a controller, such as a PLC, or a measurement apparatus such as an oscilloscope or multimeter, then its at least one input circuit provides at least input of the controller or measurement apparatus or defines or implements at least one such controller or measurement apparatus.

In an expedient manner, the inventive input facility comprises at least one input terminal, such as at least one input pin. The at least one input circuit of the inventive input facility can begin with the at least one input terminal, in particular input pin. At least one input terminal can, in other words, be a first component of the of the respective input circuit. The input circuit can, however, in principle also begin after one or a plurality of input terminals, possibly be connected to these.

The inventive input facility can provide or implement just one or also a plurality of analog inputs and/or just one or also a plurality of digital inputs for a controller or measurement apparatus.

In this manner, for example, a multichannel embodiment can be present. By comparison with the realization of a conventional ADC on the process side, the phase modulation converter has the further advantage that then a separate complete converter does not have to be constructed for each channel. In particular, it is sufficient for one amplitude modulator, adder and limiter to be present per channel, while one central demodulation facility can be used for a plurality of channels. In other words, a plurality of channels in particular be realized by scaling of the element upstream of the demodulation facility with simultaneous use of a single, central demodulation facility. A scaling of all components of the demodulation facility, which can also be referred to as the demodulator, is not needed. In particular, a plurality of FPGAs and/or ASICS do not have to be provided. A scaling within the demodulation facility, such as within an FPGA ASIC, to a plurality of channels that are converted simultaneously can be provided and is possible without any problem. This offers clear cost advantages in a direct comparison.

In an especially advantageous embodiment of the inventive input facility, the at least one phase modulation converter is formed with multiple channels. By providing a multi-channel phase-modulation converter, a multi-channel input facility can be obtained in a simple manner. Such a facility expediently has a plurality of input terminals, such as input pins, in specific terms one for each channel.

It is further preferable that the at least one multi-channel phase modulation converter comprises a central demodulation facility and for each channel a separate amplitude modulator, a separate adder and a separate limiter, where the limiters of the number of channels are connected to the central demodulation facility, so that the central demodulation facility is supplied from the number of limiters with output signals in each case and there is sampling therein with at least one sampling clock signal. The connection is a signaling connection. The number of limiters can be connected directly or also via further elements to the central demodulation facility.

In the industrial environment, above all there often exist applications for which a plurality of channels on the process side work on a common ground potential. The inventive input facility can be configured accordingly.

The inventive input facility can further comprise at least one signal processing module. This is then in particular connected upstream of the at least one phase modulation converter. Preferably, the least one signal processing module comprises at least one resistor and/or at least one diode, in particular Zener diode, and/or at least one transistor. An output of the or of the respective signal processing module can be connected to an input of the or of the respective amplitude modulator, directly or also via further elements. If the input facility has at least one multi-channel phase modulation converter, then in an expedient manner a plurality of, in particular a number corresponding to the plurality of channels, of signal processing modules are connected upstream of the phase modulation converter, where one signal processing module is assigned to one of the channels in each case.

In controllers, such as PLC modules, with a plurality of digital channels, depending on the application case or user application, the requirement can arise for all channels present to be frozen and read at a fixed point in time. Above all with electrically isolated channels this represents a challenge that can be resolved especially easily in the inventive manner by using at least one phase-modulation converter.

With a multi-channel embodiment there can be provision in a development for the amplitude modulators of the number of channels to be connected to the central demodulation facility. Here, the connection is also a signaling one, which can be available both directly and also via further elements.

It is then further preferably that the input facility is configured such that the amplitude modulators of the number of channels can be clocked via the central demodulation facility, in particular by a clock generator facility of this, and/or such that the amplitude modulators of the number of channels can be supplied with at least one carrier signal generated by the central demodulation facility, in particular by a clock generator facility of this.

Then, in an especially simple manner, a “gating” of the input state at a specific point in time clock-synchronously for the number of channels or for inputs defined for these can be achieved.

The inventive input facility can be formed as an input module of a or for an in particular industrial controller or of or for an in particular industrial measuring apparatus. The inventive input facility can be formed as modular.

If the inventive input facility has more than one input circuit in order to provide more than one input, then there can each input circuit can comprise at least one phase modulation converter.

If the inventive input facility comprises at least one multi-channel phase modulation converter, then one of the channels can form or implement an input in each case.

In a further especially advantageous embodiment, the demodulation facility of the at least one phase-modulation converter comprises at least one FPGA and/or at least one ASIC or is implemented on at least one FPGA and/or on at least one ASIC.

Further subject matter of the invention is a controller, in particular a programmable logic controller, which comprises at least one inventive input facility. Here, it has proven to be quite especially suitable for at least the demodulation facility of at least one phase-modulation converter of the input facility to be implemented on a backplane bus ASIC of the controller. The demodulation facility and, where necessary further components of the input facility can, in other words, be integrated directly into a backplane bus of the controller, which proves to be especially space-saving and efficient.

The invention also relates to a measurement apparatus, in particular to an oscilloscope or preferably digital multimeter, which comprises at least one inventive input facility.

The inventive input facility then, in an expedient manner, defines at least one digital and/or at least one analog input of the controller/measurement apparatus or provides such an input. A (modular) input module can be involved, which is an element of the controller or measurement apparatus and provides one or more inputs of the apparatus.

It should be noted that, in the industrial environment, the input variables or input signals which, for example, can originate from at least one sensor, such as a sensor for detecting a pressure, a temperature or also another physical measurement variable, are analog as a rule. Also a digital input or a digital channel of such a sensor can accordingly be used for analog signals and is used as a rule for such signals. A digital input or channel of such an apparatus is to be particularly understood as an input or channel with which or in which an interpretation of the information in two states is possible or occurs.

The subject matter of the invention is also the use of an inventive input facility in an in particular programmable logic controller or a measurement apparatus, in particular an oscilloscope or preferably digital multimeter.

Lastly, the subject matter of the invention is the use of a phase-modulation converter, comprising an amplitude modulator with carrier suppression to which an input signal can be supplied on the input side to obtain a carrierless amplitude-modulated signal, an adder for adding to the carrierless amplitude-modulated signal a preferably sinusoidal carrier signal shifted by 90° and for obtaining a phase-modulated signal, a limiter to which the phase-modulated signal is supplied and with which a noise amplitude modulation in the phase-modulated signal can be suppressed, and a demodulation facility to which the signal output from the limiter is supplied and within which there can be sampling with at least one sampling clock signal, where the phase-modulation converter is used in an input circuit of a preferably programmable logic controller or in an input circuit of a measurement apparatus, in particular of an oscilloscope or of a preferably digital multimeter.

There can be provision for the inventive input facility to be used for shared transmission of signal information and diagnostic information over a channel. In the same manner, there can be provision for the phase modulation converter to be used for shared transmission of signal information and diagnostic information over a channel.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

Further advantages and features of the present invention will become clear with the aid of the description given below, which refers to the enclosed drawing, in which:

FIG. 1 shows a purely schematic diagram of an exemplary embodiment of an inventive programmable logic controller, which comprises at least one inventive input module;

FIG. 2 shows a purely schematic, enlarged diagram of the input module of the controller of FIG. 1;

FIG. 3 shows an enlarged, purely schematic diagram of clock generator facility, XOR module, integrator and further components of the demodulation facility of the input module of FIG. 2;

FIG. 4 shows a purely schematic diagram of a clock generator facility, XOR module, integrator and further components of an alternatively embodied demodulation facility for the use of sampling clock signals;

FIG. 5 shows an enlarged, purely schematic diagram of the three clock generation blocks of the clock generator facility of the demodulation facilities in accordance with FIGS. 3 and 4;

FIG. 6 shows, in a purely schematic diagram, a further exemplary embodiment of an inventive input module in a multi-channel embodiment; and

FIG. 7 shows an enlarged, purely schematic diagram of the demodulation facility of the multi-channel input module of FIG. 6.

### DETAILED DESCRIPTION OF THE EXEMPLARY EMBODIMENTS

In the figures, elements and components that are the same or similar are provided with the same reference numbers.

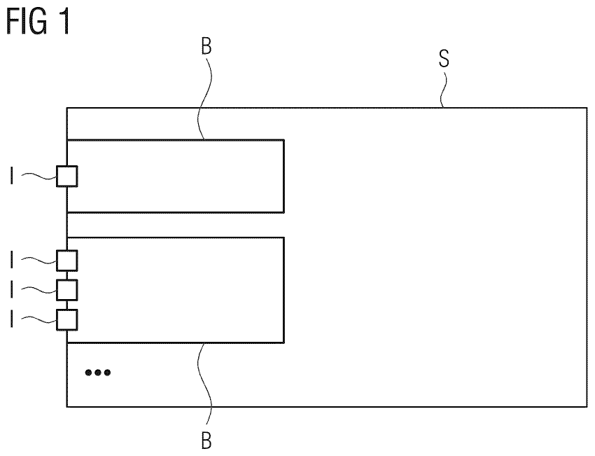

In a simplified, schematic block diagram FIG. 1 shows an exemplary embodiment of an inventive controller S. In the present exemplary embodiment, this is formed as a programmable logic controller (PLC).

The controller S comprises at least one input facility, which is formed as a preferably modular input module B. Two input modules B are shown in FIG. 1, a single-channel module with one input terminal, in particular input pin I, and a multi-channel module with three input-side terminals or terminal points I. However, this is to be understood as being purely exemplary. The controller S can also comprise only one input module B or more than two input modules B, which can each be formed both as single-channel and also as multi-channel modules. The number of three input terminals I in the multi-channel variant from FIG. 1 is also purely exemplary. A multi-channel input module in accordance with the present invention can also define just two or more than 3, such as 4, 5, 6, 7, 8 or more inputs for the controller S. The input-side terminals or terminal points I of the input modules B form input-side terminals or terminal point I of the controller S.

It is also to be understood as being exemplary that the apparatus shown in in FIG. 1 is formed as a controller S. As an alternative, this could also be implemented by a measurement apparatus, where an oscilloscope or a (digital) multimeter might be given as examples for such an apparatus.

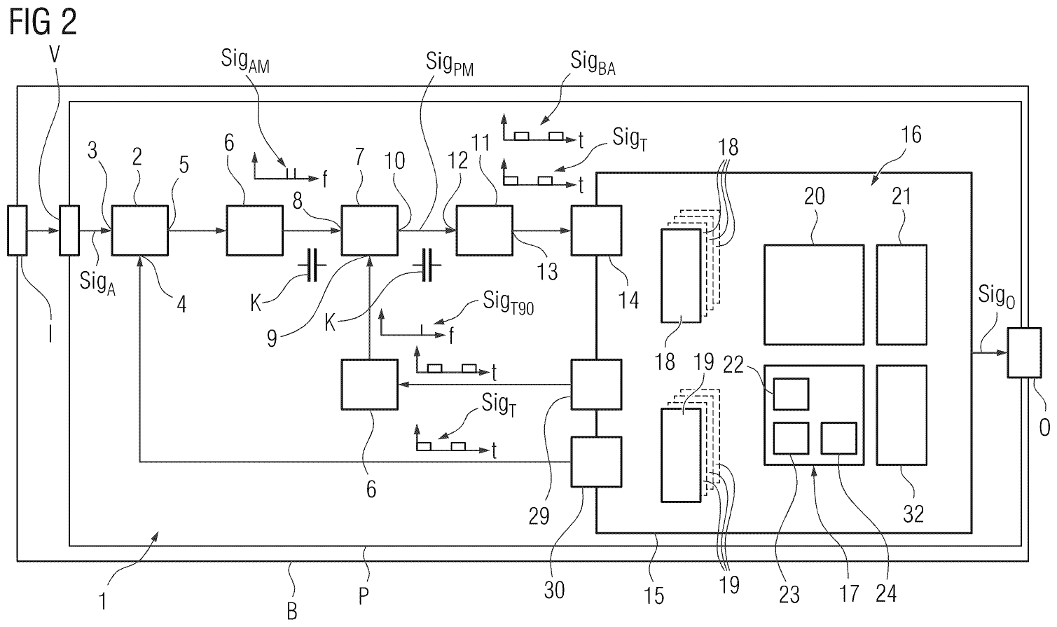

The, or in the case of more than one, the respective input module B (cf. FIGS. 1 and 2) comprises at least one input circuit 1 for providing at least one digital and/or at least one analog input for the controller S or measurement apparatus.

As evident from the enlarged diagram from FIG. 2, the input circuit 1, as well as the input-side terminal point I has an output-side terminal point O, which in the example shown also form corresponding terminal points of the input module B. The terminal points I, O can involve terminal pins. The input circuit 1 further optionally comprises a signal processing module V connected downstream from the input-side terminal point I, in particular serving for signal conditioning which, for example, has at least one resistor and/or at least one diode, in particular a Zener diode, and/or at least one transistor, which are not shown separately in the simplified FIG. 2.

Connected after the signal processing module V is a phase modulation converter P. This represents an analog-digital converter. The input signal Sig_{A}, which can involve an analog, but also a digital signal, can be supplied via the terminal point I, and can reach the phase modulation converter P via the optionally provided signal processing module V. The phase modulation converter P comprises an amplitude modulator 2 with carrier suppression, to which an input signal Sig_{A} can be supplied at the input 3 or is supplied during operation. The amplitude modulator 2 is configured to obtain a carrierless amplitude-modulated signal Sig_{AM} from the input signal Sig_{A}, which is transmitted via two differential lines to the subsequent stages. It should be noted that the two lines for the differential transmission are not shown separately in the Figures, but just one is shown for the sake of simplicity. The amplitude modulator 2 can, for example, involve a switch modulator or a ring modulator. A switch modulator can in this case comprise at least one in particular digital switch and/or at least one mechanical relay and/or at least one reed relay and/or at least one Micro-Electro-Mechanical Systems (MEMS) switch or be provided by these.

At a second input 4 the amplitude modulator 2 is supplied with a square-wave or sinusoidal carrier signal Sig_{T}, the generation of which will be discussed in greater detail below. The amplitude-modulated signal Sig_{AM} emerges as a differential signal for the output 5 of the amplitude modulator 2.

The amplitude-modulated signal Sig_{AM} subsequently passes through an analog filter 6 connected downstream from the amplitude modulator 2 and is supplied to adder 7 of the apparatus 1, again connected downstream, via its input 8. A further square-wave or sinusoidal carrier signal Sig_{T90}, which is phase-shifted by 90° in relation to the sinusoidal carrier signal Sig_{T} is supplied to the adder 7 at a further input 9. By adding the carrierless amplitude-modulated signal Sig_{AM} and sinusoidal carrier signal Sig_{T90}, a phase-modulated signal Sig_{PM} with noise amplitude modulation is obtained.

The signal Sig_{PM} is output at an output 10 of the adder 7 and supplied to a limiter 11 via its input 12. The limiter 11 is configured to suppress a noise amplitude modulation in the signal Sig_{PM}. The obtained signal Sig_{BA}, which is also referred to here as the limited signal, emerges at the output 13 of the limiter 11.

The signal Sig_{BA} now carries the modulation in temporally different zero crossings by comparison with the 90° carrier signal Sig_{T90} or the suppressed carrier signal Sig_{T}. This is shown purely schematically in FIG. 2 at the top to the right of the limiter 11. The figure shows, in a graph plotted against time in each case, the signal Sig_{BA} (above) and the signal Sig_{T} (below) as well as the temporal offset Δt. The amplitude of the signal Sig_{BA} fluctuates between 0 and 1, i.e., a signal digital in its amplitude has been obtained.

The limited signal Sig_{BA} is supplied to an input 14 of a digital circuit part 15, which serves to demodulate the signal Sig_{BA} and optionally further purposes. It should be noted, even if in FIG. 2 no further components are shown between the limiter 11 and the digital circuit part 15, it is by no means excluded that such components are present. In other words, the limited signal Sig_{BA} can be supplied to the digital circuit part 15 directly or also via further components, which can also require a further processing of the signal.

Furthermore, it should be noted that a coupling capacitor K can be provided in each case, for example, between the analog filter 6 and the analog adder 7 and also between the adder 7 and the limiter 11, which is indicated accordingly in FIG. 2. The pair of coupling capacitors K is used for galvanic isolation or forms such isolation, which in the case of a phase-modulation converter 1 can be provided very simply and almost at any point in the signal path P up to the digital circuit part 15, which represents a significant advantage of the phase-modulation converter 1.

The digital circuit part 15 can comprise at least one FPGA and/or ASIC or be implemented by at least one FPGA and/or ASIC. In the exemplary illustrated embodiment, the digital circuit part is implemented by an ASIC 15. The ASIC 15 involves a backplane bus ASIC 15 of the PLC S.

Implemented on the ASIC 15 is a demodulation facility 16 of the apparatus 1, via which digital demodulation of the limited signal Sig_{BA} can be performed. The demodulation facility 16 can also be referred to as a digital demodulator. In other words, this is integrated in the backplane bus ASIC 15 present in any case of the controller S, which has proved to be especially advantageous.

With the framework of the demodulation there is, inter alia, sampling of the signal Sig_{BA} via at least one sampling clock signal CLK0, CLK1, CLK2, CLK3, a comparison with a reference signal Sig_{RF} likewise sampled with the at least one sampling clock signal and an integration of the comparison, where the generation of the reference signal Sig_{RF} and the comparison is discussed in more detail below.

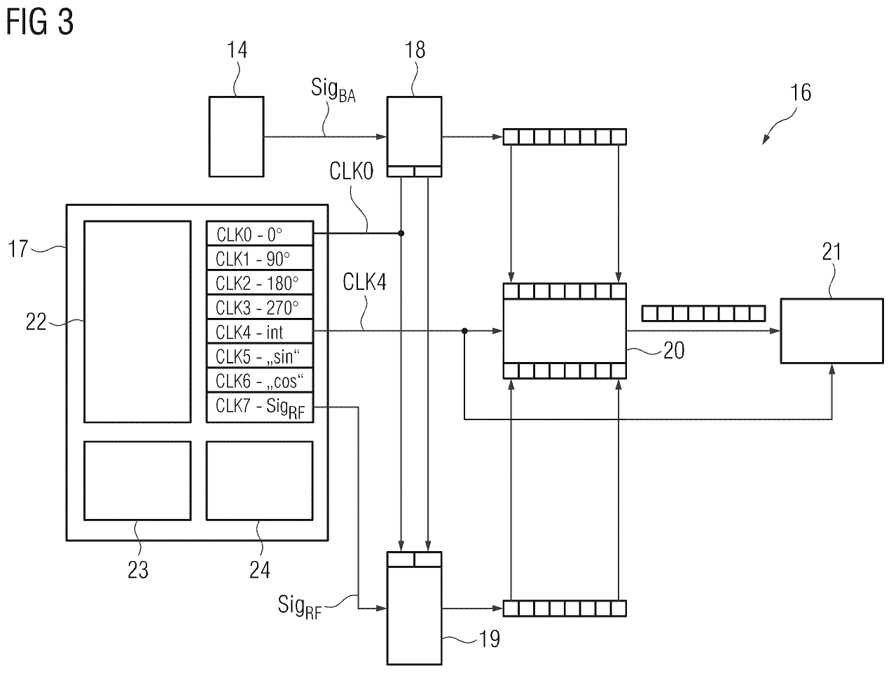

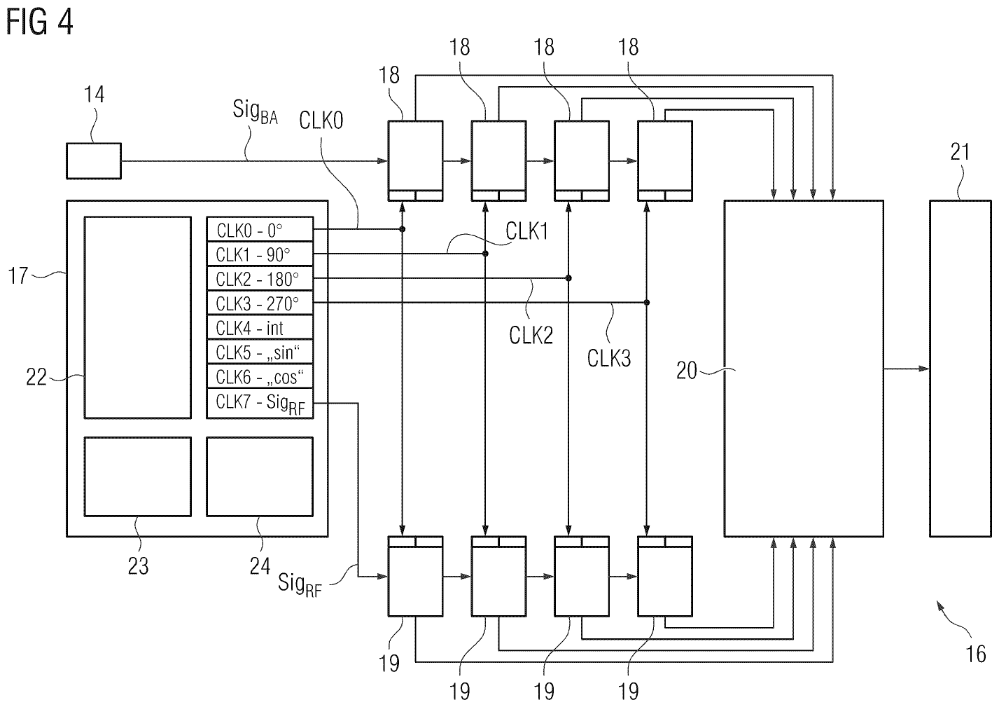

FIG. 3 contains a purely schematic block diagram for the digital demodulation using the demodulation facility 16 for the case in which the sampling is undertaken with a sampling clock signal CLK0. FIG. 4 shows an alternative exemplary embodiment for the use of a plurality of sampling clock signals for the sampling, here of four sampling clock signals CLK0, CLK1, CLK2, CLK3, for example.

The demodulation facility 16 comprises a clock generation facility 17 and at least one buffer 18 for the limited signal Sig_{BA}, which is preferably implemented by a FIFO buffer, and is referred to here as the signal buffer 18. Furthermore, at least one further buffer 19 is provided for the reference signal Sig_{RF}, which is likewise preferably configured as a FIFO buffer and, to distinguish it from the buffer 18 for the signal Sig_{BA}, is referred to as the reference buffer 19. It should be noted that, despite these different designations, the at least one signal buffer 18 and the at least one reference buffer 19 area can be formed with the same configuration and are formed with the same configuration, here.

The number of signal buffers 18 and the number of reference buffers 19 expediently matches and corresponds in each case to the number of sampling clock signals CLK0, CLK1, CLK2, CLK3 used. The demodulation facility 16 shown in FIG. 3 thus comprises exactly one signal buffer 18 and exactly one reference buffer 19.

FIG. 4 shows by way of example that four sampling clock signals CLK0, CLK1, CLK2, CLK3 can be used for sampling the limited signal Sig_{BA} and simultaneously the reference signal Sig_{RF}. The demodulation facility 16 from FIG. 4 accordingly comprises four, preferably identical, signal buffers 18 and four, preferably identical, reference buffers 19. In FIG. 2, for reasons of clarity, the buffers 18, 19 are shown behind one another and the frontmost buffer 18, 19 is shown with a solid line, while the buffers 18, 19 lying behind it are shown with a dashed line, in order to illustrate that these can optionally additionally be present.

Connected downstream of the buffers 18, 19 and connected to the outputs of the buffers 18, 19 is an XOR module 20, which comprises an XOR gate or can be implemented by such a gate. Specifically, the output of the at least one signal buffer 18 is connected to an input of the XOR module 20 and the output of the at least one reference buffer 19 is connected to the other input of the XOR module 20, such that values output can be transferred to this and compared. In the exemplary embodiment from FIG. 4, the outputs of all four signal buffers 18 are connected to one input of the XOR module 20 and the outputs of all four reference buffers 19 are connected to the other input of the XOR module 20.

Beyond this, an integrator 21 connected downstream of the XOR module 20 is present, via which the values output by the XOR module 20 can be integrated.

In the exemplary embodiment illustrated in FIGS. 3 and 4, the clock generation facility 17 of the demodulation facility 16 comprises three clock blocks 22, 23, 24 in all. With these three clock blocks 22, 23, 24, a total of seven clock signals CLK0, CLK1, CLK2, CLK3, CLK4, CLK5, CLK6, CLK7 are generated, also the sampling clock signals CLK0 (FIG. 3) or CLK0, CLK1, CLK2, CLK3 (FIG. 4) used for the sampling. It should be noted that the clock blocks 22, 23, 24 can also be referred to as clock modules.

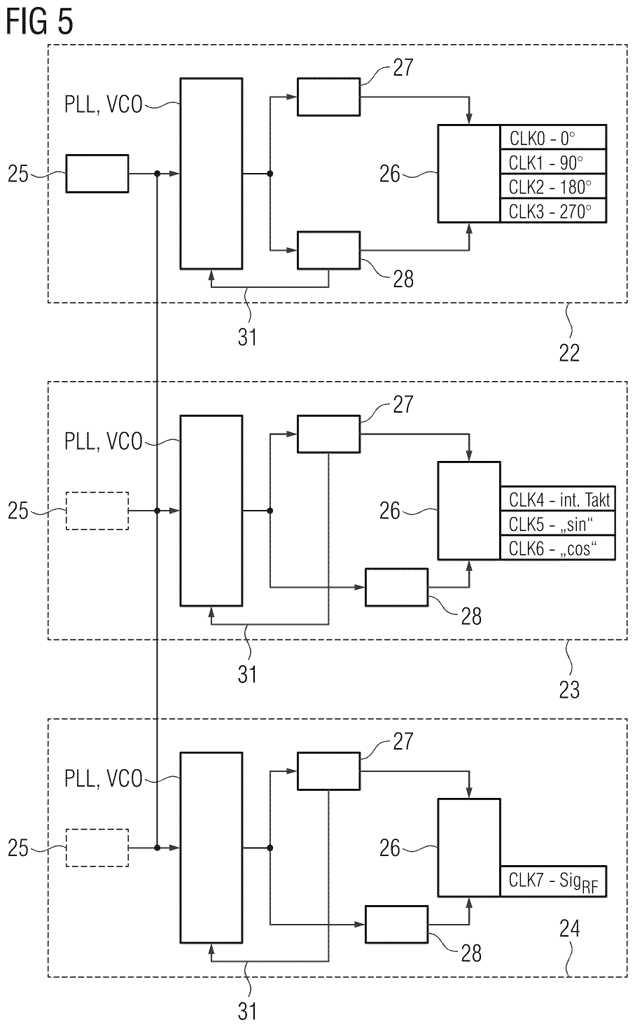

Each of the clock blocks 22, 23, 24 comprises in this case a phase locked loop PLL with a voltage-controlled oscillator VCO. The internal structure of the three clock blocks 22, 23, 24 is shown, once again greatly simplified and purely schematically, in FIG. 5. Here, the phase locked loop PLL with voltage-controlled internal oscillator VCO of the respective clock block 22, 23, 24 is shown simplified as a block element.

The internal oscillator VCO of each clock block 22, 23, 24 is regulated to an external reference signal from an external clock source 25 which, for example, can be given by a quartz resonator, with a correspondingly set factor to a higher inner frequency f_{VCO}. The three clock blocks 22, 23, 24 can be supplied from the same external clock source 25, which does not absolutely have to be the case however.

The clock blocks 22, 23, 24 can, for example, each be implemented by a Mixed-Mode Clock Manager (MCM) module or block or can comprise such a module. The manufacturers Xilinx or AMD for example offer FPGAs with such modules or blocks. FPGAs from Lattice Semiconductor should be mentioned as further examples, in particular the EPS, ECP5, EPC5-5G series, which likewise make possible a fine division of the phase and do so with up to 300 steps.

Each of the clock blocks 22, 23, 24 has a plurality of clock outputs, which are indicated in FIG. 5 by a block element provided, labeled with a reference number of 26. Each clock output can assume various dividers, and thus frequencies, and various permanently defined phase positions. All clocks are derived in this case from f_{VCO}. As well as the block element 26 representing the clock outputs there are the sampling clock signals CLK0, CLK1, CLK2, CLK3, CLK4, CLK5, CLK6, CLK7 generated and output by the respective clock block 22, 23, 24 in the exemplary embodiment shown. The corresponding numbering CLK0, CLK1, CLK2, CLK3, CLK4, CLK5, CLK6, CLK7 is also to be found in FIGS. 3 and 4, this alongside arrows for their actual use, which is discussed in detail below. Each clock block 22, 23, 24 or its oscillator VCO has both phase-locked taps 27 and also at least one phase-variable tap 28. The phase-variable tap 28 makes possible a subdivision of the phase position into fine steps. In the illustrated forms of embodiment, there can be a subdivision into 56 steps, i.e., into steps of 360°/n with n=56. The number of 56 steps is to be understood in this case as being exemplary.

The clock block 22 is used to provide the fast sampling clocks, i.e., sampling clock signals, for the sampling of both the limited signal Sig_{BA}, and also of the reference signal Sig_{RF}. In the example in accordance with FIG. 3, it involves the sampling clock signal CLK0, in the sampling in accordance with FIG. 4, the sampling clock signals CLK0, CLK1, CLK2, CLK3.

256 MHz is mentioned purely by way of example for a frequency of the fast sampling clock signals CLK0, CLK1, CLK2, CLK3 used for the sampling, which are derived from f_{VCO}. f_{VCO} can, for example, amount to 1024 MHz. Naturally, other frequencies are also possible. It is expediently true to say that the frequency of (respective) sampling clock signals CLK0, CLK1, CLK2, CLK3 lies above the modulator frequency of the amplitude modulator 2 by at least one order of magnitude, preferably by two orders of magnitude.

The second clock block 23 serves to generate slow internal signals. In the exemplary illustrated embodiment, this generates the clock signals CLK4, CLK5 and CLK6. CLK4 is a slow internal clock, which amounts to 32 MHz in the present example, which once again is to be understood as being exemplary and which is used for the buffers 18, 19 and also the XOR module 20 and the integrator 21, which is indicated in FIG. 3 by corresponding arrows. CLK5 corresponds to a square-wave or sinusoidal signal, CLK6 to a signal offset by 90° to the square-wave or sinusoidal signal, i.e., in particular a cosine signal. The square-wave or sinusoidal signal is output via an output 29 of the ASIC 15 in the direction of the adder 7 in order to obtain Sig_{T90} and supply it to the input 9 of the adder 7. Via an output 30 of the ASIC 15 the cosine signal is output as Sig_{T} in the direction of the amplitude modulator 2, in concrete terms to its input 4. It should be noted that an analog filter 6 is still located between the output 29 of the ASIC 15 and the input 9 of the adder 7. On the other hand, such a filter is not shown between the output 30 of the ASIC 15 and the input 4 of the amplitude modulator 2, even if it is not excluded that such a filter is likewise located here.

The third clock block 24 serves to generate CLK7, which corresponds to the reference signal Sig_{RF} or is used for the generation thereof. This involves a purely internal signal, which does not leave the ASIC 15.

The three clock blocks 22, 23, 24 can essentially match in their structure. One difference between the clock block 22 and the blocks 23 and 24, however, consists of the feedback path 31 of the phase-locked loop PLL or of its oscillator VCO being connected to the phase-variable tap 28 of the oscillator VCO, while in the clock modules 23 and 24 the feedback path 31 is connected to a phase-locked tap 27 (cf. FIG. 5).

In operation of the apparatus, in the case of FIG. 3, the one signal buffer 18 serves to sample the limited signal Sig_{BA} with the fast sampling clock signal CLK0, or in the case of FIG. 4 with the four signal buffers 18 to sample the limited signal Sig_{BA} with the four fast sampling clock signals CLK0, CLK1, CLK2, CLK3 with a fixed phase offset to one another as well as the synchronization to the slower internal clock domain. On the input side, the limited signal Sig_{BA} is supplied for sampling to the (respective) signal buffer 18. The (respective) signal buffer 18 receives both one of the fast sampling clock signals CLK0, CLK1, CLK2, CLK3 for sampling, this from the clock block 22, and also the slower internal clock signal CLK4, to which there is synchronization by means of the (respective) signal buffer 18, this by the clock block 23. It should be noted that in FIG. 4, for use of the number of clock signals CLK0, CLK1, CLK2, CLK3 and associated buffers 18, 19, the arrows for the slower internal clock CLK4 are not inserted additionally for reasons of clarity.

The (respective) signal buffer 18 has an input with a bit width of 1 and an output with a bit width of 8. The ratio of the bit widths from input to output of the (respective) signal buffers 18 is chosen as similar to the ratio of the clocks CLKi/CLK4, with i=0, 1, 2, 3, or vice versa. In the example described here CLKi/CLK4=256 MHz/32 MHz=8, with i=0, 1, 2, 3.

Whenever 8 sampling values are “accumulated” in a signal buffer 18, this number of values is output from the signal buffer 18 and is output to the XOR module 20. The values are output with the slower clock of CLK4, i.e. 32 MHz in this case. It can also be said that the (respective) signal buffer 18 delivers as output the “fully sampled” digital limited signal Sig_{BA} in the temporally correct order.

For the (respective) reference buffer 19 what has been stated above applies fully analogously, with the difference that this is not supplied with the limited signal Sig_{BA}, but with the reference signal Sig_{RF} for sampling with the (respective) fast sampling clock signal CLK0, CLK1, CLK2, CLK3 and for synchronization to CLK4, as indicated in FIGS. 3 and 4 schematically by associated arrows.

The “fully sampled” digital reference signal, which is clocked with the same clock signal CLK0 or with the same clock signals CLK0, CLK1, CLK2, CLK3 is thus obtained from the (respective) reference buffer 19. Thus, the temporal sequence for the “fully sampled” limited Sig_{BA} signal matches that of the signal obtained from the signal buffer or buffers 18.

In the embodiment illustrated in FIG. 4 with the four sampling clock signals CLK0, CLK1, CLK2, CLK3, each signal buffer 18 in this case outputs another part of the signal. Each sampling domain delivers a data block. In the same domain, in line with this the reference signals Sig_{RF} are “sampled”. Then, in the XOR module 20 a “block-by-block” comparison is possible.

To achieve an increased resolution, there can optionally be provision, with the framework of the sampling for the phase position of the one sampling clock signal CLK0 (FIG. 3) or of the number of sampling clock signals CLK0, CLK1, CLK2, CLK3 (FIG. 4), which are used for the sampling of the limited signal Sig_{BA} and the reference signal Sig_{RF}, to be dynamically changed. For this, the feedback path 31 of the clock block 22 for the generation of the fast clock signals CLK0, CLK1, CLK2, CLK3, as mentioned above, is connected to the phase-variable tap 28 of the oscillator VCO.

The phase position of the signal fed back to the oscillator VCO via the feedback path 31 is continuously or repetitively changed. This preferably occurs cyclically for example every couple of microseconds, such as every 42 microseconds. The shifting of the phase position is undertaken in such cases by steps of 360°/56 in each case and in the same direction. A logic 32 is provided (cf. FIG. 2), which is preferably implemented on ASIC 15, which also comprises or forms the demodulation facility 16, and which the corresponding controller converts for the dynamic phase position change of the sampling clock signals. The logic 32 can be a component of the demodulation facility 16.

In the exemplary embodiment illustrated in FIG. 4, the number of sampling clock signals CLK0, CLK1, CLK2, CLK3 are all generated from the output signal of the one oscillator VCO of the clock block 22. Accordingly, the repeated changing of the phase position of the feedback signal results in a repeated changing of the phase positions of all sampling clock signals CLK0, CLK1, CLK2, CLK3 used for the sampling synchronously and by the same-size steps.

Through the stepping of the feedback signal over the feedback path 31 the phase position of all CLK outputs of the clock module 22 also changes synchronously for each phase step of the oscillator VCO. The individual sampling clock signals CLK0, CLK1, CLK2, CLK3 can additionally continue to be rigidly offset in relation to one another by 90°.

In the case described, a phase step of

$${t}_{STEP} = 1 / ( 768 MHz * 56 ) = 1 / 43.008 GHz = 23.25 ps .$$

The 256 MHz sampling clocks CLK0-CLK3 offset from one another by 90° means that only a phase difference of

$${t}_{diff} = 1 / ( 256 MHz * 4 ) = 976.56 ps$$

must be bridged to cover all possible discrete sampling points by means of the finely stepped phase steppings. In ASIC 15, 42 (976.56 ps/23.25 ps) periods of the modulator frequency are summed.

The computational solution is produced as

$$log 2 ( 90 ° / 360 ° * 43008 MHz / 1 MHz ) = 13.39 bits$$

without changing the frequency of the amplitude modulator 2.

The data rate reduces from 1 MHz to 1 MHz/42=23.8 kHz.

By contrast, without the dynamic phase shifting, a computational solution would be produced of

$$log 2 ( 90 ° / 360 ° * 4 * 256 MHz / 1 MHz ) = 8 bits .$$

As emphasized above, the resolution increase by the dynamic phase shifting is optional. In particular, for the case in which one or more digital inputs is provided, as a rule a lower resolution can also suffice. Accordingly, the modulator frequency of the amplitude modulator 2 can also be increased. With this, on the one hand, the data rate increases and, on the other hand, filter elements can once again be significantly smaller.

It would also be conceivable to employ integrated filters, as are used in large volumes in the RFID/ISM area. For example, filters for frequencies of 13.56 MHz or 27 MHz or 40 MHz or 433 MHz should be mentioned.

With the same architecture, despite this a resolution of

$$log 2 ( 90 ° / 360 ° * 43008 MHz / 13.56 MHz ) = 9.6 bits ( RFID frequency )$$

or a resolution of

$$log 2 ( 90 ° / 360 ° * 43008 MHz / 315 MHz ) = 5.09 bits ( SAW filter for ISM band )$$

would still be produced, which is still sufficient for establishing in particular a digital state.

With the XOR modules 20 connected downstream of the buffers 18, 19, it is established following on from the fast sampling (with or without dynamic phase shifting) and the synchronization at what points in time the limited signal Sig_{BA} and the reference signal Sig_{RF} are different. The subsequent integration via the integrator 21 produces the modified value, which is output as Sig_{O} from the ASIC 15 or will initially be further processed (cf. FIG. 2).

In an expedient manner, there is integration in each case until such time as the dynamic change of the phase position of the sampling clock signals CLK0, CLK1, CLK2, CLK3 described here has occurred over an angular range of 360°/m, where m corresponds to the number of sampling clock signals used for the sampling of the limited signal Sig_{BA}. The inventive apparatus 1, in particular its demodulation facility 16 or an FPGA 15 of the apparatus, can be configured accordingly.

Particularly for the case in which there is no dynamic change of the phase position of the sampling clock signal or signals CLK0, CLK1, CLK2, CLK3, a new converted digital value is produced with each period.

Sig_{O} is in particular a digital signal or digital value in the range of values of, for example, 0 to 2^{a} with the resolution a of the phase-modulation converter P. This digital value can be forwarded or further processed and supplied for use. There can be, for example, provision, for the case of a “digital input”, for there to be a comparison with a threshold value and then only 1 bit (0/1) being forwarded per channel C1, C2, . . . , Cn, in order to keep the amount of data as small as possible.

It should be noted that preferably, independent of whether the input signal Sig_{A} at the input-side terminal point I, such as PLC terminal, is analog or digital, the signal is considered to be an analog value particularly up to the demodulation facility 16 or through the demodulation facility 16. Only during the interpretation of the value can a (superordinate) logic then decide whether the signal is now digital or describes a value, especially a process variable, in an analog manner.

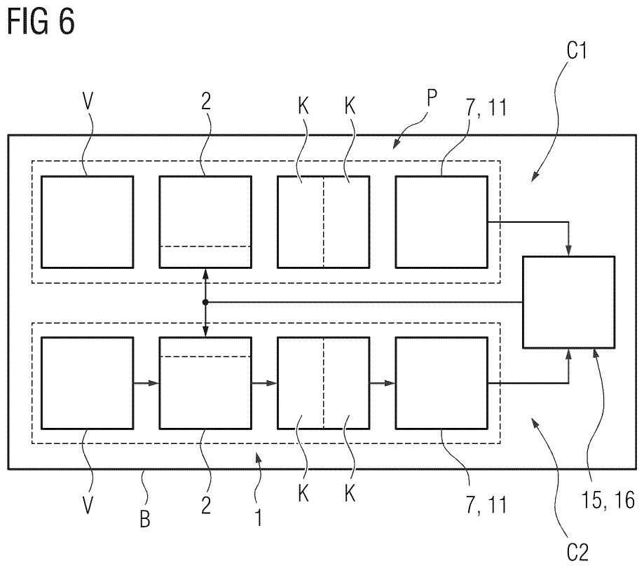

FIG. 6 shows, in a purely schematic diagram, a further exemplary embodiment of an inventive input facility in the form of an input module B. This can likewise be a component of a programmable logic controller not shown in any greater detail or also of a measurement apparatus. The example in accordance with FIG. 6 is formed as multi-channeled in this case, specifically as a two-channel apparatus. For this, it comprises an input circuit 1 with a multi-channel phase modulation converter P. It should be noted that FIG. 6 is intended to show the basic structure of a multi-channel configuration, where, for reasons of clarity, only a few of the components of the input circuit 1 and of its phase-modulation converter P are shown, these being partly even more simplified than in FIG. 1.

As evident, a separate signal processing module V is present for each of the two channels C1, C2. Also provided for each channel C1, C2 are a separate amplitude modulator 2, at least one galvanic isolation with two coupling capacitors K, and also a separate adder 7 and limiter 11. In other words, these components scale with the number of channels C1, C2.

By contrast, the phase modulation converter 2, despite the multi-channel embodiment, comprises just one central demodulation facility 16, which is preferably implemented on an FPGA or ASIC 15. The limiters 11 of the number of, here two, channels C1, C2 are connected in this case to the central demodulation facility 16, so that the central demodulation facility 16 is supplied with signals Sig_{BA} output in each case from the number of limiters 11 and in each case can be sampled therein with at least one sampling clock signal CLK0, CLK1, CLK2, CLK3. The connection is a signaling connection. The number of limiters 11 can be connected directly or also via further elements to the central demodulation facility 16.

By comparison with the realization of a conventional ADC on the process side, the phase modulation converter 2 has the further advantage that a separate complete converter for each channel C1, C2 does not have to be constructed. There is also no need for the complete generation of the supply voltages, references and the filters necessary for each channel for the converter, which is frequently more expensive than the actual converter, both with regards to costs and also to space on the printed circuit board. The present solution, on the other hand, is markedly leaner and lower-cost. In particular, a separate FPGA or ASIC 15 is also not required for each channel.

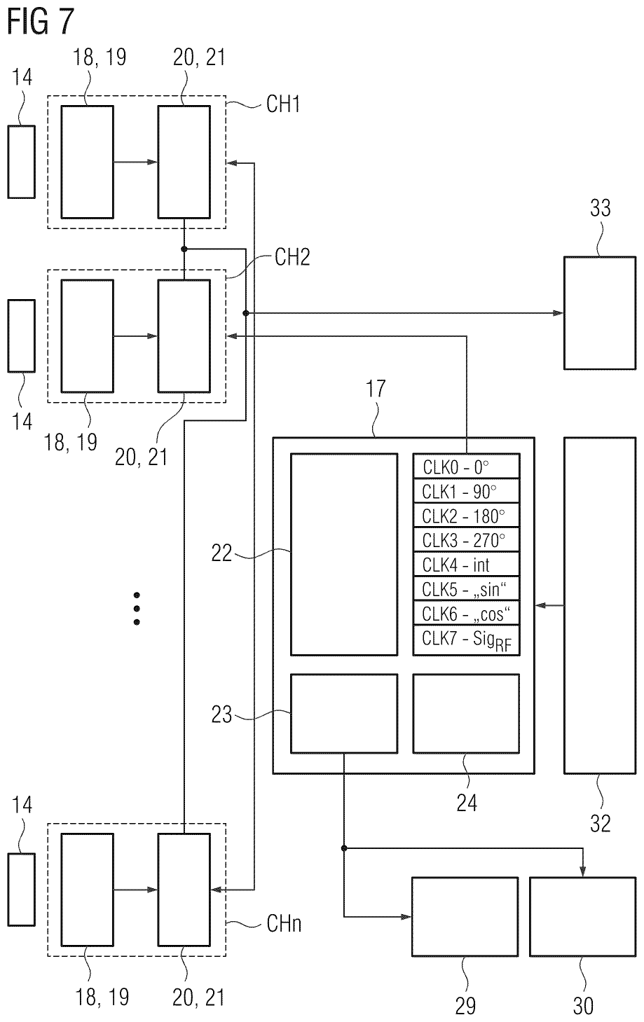

There can be provision for a scaling within the one ASIC 15 (or alternatively of an FPGA) for the number of channels C1, C2, . . . , Cn. This is shown (purely schematically) in FIG. 7.

An ASIC input 14 is provided on the ASIC 15 in this case for each channel C1, C2, . . . . Cn, as well as separate buffers 18, 19, a separate XOR module 20 and a separate integrator 21. The functioning for each channel C1, C2, . . . , Cn, is as described in detail above in conjunction with FIG. 3 for the use of a sampling clock signal CLK0 and in conjunction with FIG. 4 for the use of four sampling clock signals CLK0, CLK1, CLK2, CLK3 for the case of just one channel.

The components “scaled-up” for the number of channels C1, C2, . . . , Cn, are connected in this case to one central clock generation facility 17. This can, as already described here with reference to FIGS. 2 to 5, comprise three clock generation modules 22, 23, 24 for example, via which clock signals CLK0, CLK1, CLK2, CLK3, CLK4, CLK5, CLK6, CLK7 can be generated, which are then used for all channels C1, C2, . . . , Cn. This is indicated in FIG. 7 by arrows, which connect the central clock generation facility 17 to the components present in multiples for the channels C1, C2, . . . , Cn, in particular the buffers 18, 19 and integrators 21.

The values output by the integrators 21 can, for example, be passed to a tapping off and preparation logic 33 present on the ASIC 15, which taps these off and prepares them, possibly for a higher logic (not shown).

As evident in FIG. 6, the ASIC 15 or the demodulation facility 16 implemented thereon are connected to the amplitude modulators 2 of the number of channels C1, C2. The input module B in this case is configured such that the amplitude modulators 2 of the number of channels C1, C2 can be clocked via the central demodulation facility 16, and/or such that the amplitude modulators 2 of the number of channels C1, C2 can be supplied with at least one carrier signal generated by the central demodulation facility 16.

Specifically, the output 30 that can also be seen in FIG. 7 is connected to each of the amplitude modulators 2 of the number of channels C1, C2 and is connected in each case to its input 4 (cf. FIG. 1). With this embodiment, a “gating” function, as is often needed for clock-synchronous reading in of inputs, in particular digital inputs, is already implicitly realized.

All channels C1, C2, . . . , Cn are derived from the same reference clock. Consequently, a clock-synchronous operation is produced automatically. Solely the delay times and the reaction times of the switch modulators 2 can still vary from channel to channel C1, C2, . . . , Cn.

In a phase modulation converter P, there is no transmission of “1 and 0”, but an analog sampling in particular of the limited signal Sig_{BA}. This is also in the case in which the phase modulation converter P is used for a digital input, i.e., for digital signals. In the analog area, it is possible, as well as the two states “1 and 0” to also cover additional states, in particular a third state. This can be used in order, together with the actual signal state, to transmit diagnostic information, such as information about a wire or line break and to do this with an additional channel C1, C2, . . . , Cn being needed. The input signal Sig_{A} can, in other words, as well as the actual signal information, comprise diagnostic information, which can be transmitted as well via the same channel C1, C2, . . . , Cn.

Through the transmission of the information about the electrical isolation K associated with the use of the phase-modulation converter in the frequency range a marked advantage as regards EM compatibility is further produced. Common Mode Faults are suppressed by the AC coupling capacitors K. Only a sensibility as regards asymmetry exists. There can, however, easily be a filtering here via low-voltage capacitors on the logic side.

Although the invention has been illustrated and described in greater detail by the preferable exemplary embodiment, the invention is not restricted by the disclosed examples and other variations can be derived herefrom by the person skilled in the art, without departing from the scope of protection of the invention.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An input facility comprising an input module for a programmable logic controller or a measurement apparatus comprising an oscilloscope or a digital multimeter, the input facility comprising:
at least one input circuit which provides at least one digital or at least one analog input for the programmable logic controller or the measurement apparatus, the at least one input circuit comprising at least one phase modulation converter, and the at least one phase modulation converter including:
an amplitude modulator with carrier suppression to which an input signal is suppliable on an input side to obtain a carrierless amplitude-modulated signal;
an adder for adding a sinusoidal carrier signal shifted by 90° to the carrierless amplitude-modulated signal and for obtaining a phase-modulated signal;
a limiter to which the phase-modulated signal is supplied and with which a noise amplitude modulation in the phase-modulated signal is suppressible; and
a demodulation facility to which the signal output by the limiter is supplied and which is sampled therein with at least one sampling clock signal.

2. The input facility as claimed in claim 1, wherein at least one electrical isolation is provided between the amplitude modulator and the demodulation facility of the at least one phase-modulation converter; and
wherein the at least one electrical isolation comprises at least a pair of coupling capacitors.

3. The input facility as claimed in claim 1, wherein the at least one phase modulation converter is formed as multi-channeled to provide a plurality of inputs;
wherein the at least one multi-channel phase modulation converter comprises a central demodulation facility and for each channel a separate amplitude modulator, a separate adder and a separate limiter; and
wherein each separate limiter of the plurality of channels is connected to the central demodulation facility, such that each signal output from the plurality of limiters is suppliable to the central demodulation facility and is sampled therein with the at least one sampling clock signal.

4. The input facility as claimed in claim 1, wherein the at least one phase modulation converter is formed as multi-channeled to provide a plurality of inputs;
wherein the at least one multi-channel phase modulation converter comprises a central demodulation facility and for each channel a separate amplitude modulator, a separate adder and a separate limiter; and
wherein each separate limiter of the plurality of channels is connected to the central demodulation facility, such that each signal output from the plurality of limiters is suppliable to the central demodulation facility and is sampled therein with the at least one sampling clock signal.

5. The input facility as claimed in claim 3, wherein each amplitude modulator of the plurality of channels is connected to the central demodulation facility;
wherein the input facility is configured such that each amplitude modulator of the plurality of channels is clocked via the central demodulation facility; and
wherein at least one carrier signal generated by the central demodulation facility is suppliable to each amplitude modulator of the plurality of channels.

6. The input facility as claimed in claim, 1 wherein the input facility has a plurality of input circuits for providing a plurality of inputs.

7. The input facility as claimed in claim 6, wherein each input circuit of the plurality of input circuits comprises at least one phase modulation converter.

8. The input facility as claimed in claim 1, wherein the demodulation facility of the at least one phase-modulation converter is implemented on at least one of (i) at least one Field Programmable Gate Array (FPGA) and at least one Application-Specific Integrated Circuit (ASIC).

9. The input facility as claimed in claim 8, wherein the input facility is formed as a programmable logic controller, and the demodulation facility of the at least one phase-modulation converter is implemented on a backplane bus ASIC of the controller.

10. The input facility as claimed in claim 1, wherein the at least one input circuit comprises a signal processing module, and the at least one phase modulation converter is connected downstream of the at least one signal processing module; and
wherein the at least one signal processing module comprises at least one of (i) at least one resistor, (ii) at least one diode formed as a Zener diode and (iii) at least one transistor.

11. The input facility as claimed in claim 1, wherein the input facility includes at least one filter configured for a frequency of one of 13.56 MHZ, 27 MHz, 40 MHZ and 433 MHz; wherein the at least one phase modulation converter of the input facility includes at least one filter configured for a frequency of one of 13.56 MHZ, 27 MHz, 40 MHz and 433 MHz.

12. A controller formed as a programmable logic controller, comprising at least one input facility as claimed in claim 1.

13. A measurement apparatus forming the oscilloscope or digital multimeter, comprising at least one input facility as claimed in claim 1.

14. The input facility as claimed in claim 1, wherein the input facility is implemented in the programmable logic controller or the measurement apparatus comprising the oscilloscope or digital multimeter.

15. A phase-modulation converter, comprising:
an amplitude modulator with carrier suppression to which an input signal is suppliable on an input side to obtain a carrierless amplitude-modulated signal;
an adder for adding to the carrierless amplitude-modulated signal a sinusoidal carrier signal shifted by 90° and for obtaining a phase-modulated signal;
a limiter to which the phase-modulated signal is supplied and with which a noise amplitude modulation in the phase-modulated signal is suppressible; and
a demodulation facility to which the signal output from the limiter is supplied and which can be sampled therein with at least one sampling clock signal;
wherein the phase-modulation converter is implemented in an input circuit of a programmable logic controller or in an input circuit of a measurement apparatus comprising an oscilloscope or digital multimeter.
